(19) United States
(12) Patent Application Publication
(10) Pub. No.: US 2026/0223577 A1
(43) Pub. Date: Jul. 30, 2026

(54) LIGHT EMITTING DISPLAY DEVICE

(71) Applicant: LG Display Co., Ltd., Seoul (KR)

(72) Inventors: Yong Hoon CHOI, Paju-si (KR); Tae Woo JEON, Paju-si (KR); Dong Myung LEE, Paju-si (KR)

(73) Assignee: LG Display Co., Ltd., Seoul (KR)

(21) Appl. No.: 19/363,202

(22) Filed: Oct. 20, 2025

(30) Foreign Application Priority Data
Jan. 24, 2025 (KR) 10-2025-0011975

(51) Int. Cl. H10K 59/80; H10K 59/122; H10K 59/38; H10K 102/00

(52) U.S. Cl. CPC H10K 59/877; H10K 59/122; H10K 59/38; H10K 2102/351

(57) ABSTRACT

Disclosed is a light emitting display device including a substrate including a red emission portion, a green emission portion, a blue emission portion, and a white emission portion spaced apart from each other, red, green, and blue color filters at the red, green, and blue emission portions, respectively, a first scattering pattern between the substrate and the green color filter, a second scattering pattern on the substrate in the white emission portion, an organic insulating layer configured to cover the red, green, and blue color filters and the second scattering pattern, a light emitting device provided on the organic insulating layer and including a plurality of first electrodes at the red, green, blue, and white emission portions to be spaced apart from each other, and a bank configured to expose the red, green, blue, and white emission portions of the plurality of first electrodes.

### CROSS-REFERENCE TO RELATED APPLICATION(S

This application claims the benefit of Korean Patent Application No. 10-2025-0011975, filed on January 24, 2025, which is hereby incorporated by reference as if fully set forth herein.

### BACKGROUND

### Technical Field

The present disclosure relates to a light emitting display device capable of improving luminance efficiency depending on changes in viewing angle and reducing lateral leakage current.

### DESCRIPTION OF THE RELATED ART

Display devices that display images on TVs, monitors, smartphones, tablet PCs, and laptops are being used in various ways and forms.

The display device includes a plurality of pixels to implement images, and has transistors to control the operation of each pixel. In addition, transistors formed through the same process as the transistors provided in the pixels are also provided in a non-active area around the plurality of pixels.

Among display devices, in order to achieve compactness and clear color display, a light emitting display device that does not have a separate light source and has light emitting elements within a display panel is being considered as a competitive application.

Meanwhile, there is growing demand for a light emitting display device that has uniform luminance at all viewing angles including a frontal viewing angle to improve image quality.

### BRIEF SUMMARY

Accordingly, the present disclosure is directed to a light emitting display device that substantially obviates one or more problems due to limitations and disadvantages of the related art.

An aspect of the present disclosure is to provide a light emitting display device having an enhanced luminance viewing angle.

Another aspect of the present disclosure is to provide a light emitting display device having a reduced luminance deviation depending on changes in viewing angle in a structure in which a light emitting device is included in common in subpixels.

Yet another aspect of the present disclosure is to provide a light emitting display device that prevents or reduces leakage current between adjacent subpixels.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

To achieve these aspects and other advantages and in accordance with the purpose of the disclosure, as embodied and broadly described herein, a light emitting display device includes a substrate including a red emission portion, a green emission portion, a blue emission portion, and a white emission portion spaced apart from each other, a red color filter at the red emission portion, a green color filter at the green emission portion, and a blue color filter at the blue emission portion, a first scattering pattern between the substrate and the green color filter, a second scattering pattern on the substrate at the white emission portion, an organic insulating layer configured to cover the red color filter, the green color filter, the blue color filter, and the second scattering pattern, a light emitting device on the organic insulating layer, the light emitting device comprising a plurality of first electrodes at the red emission portion, the green emission portion, the blue emission portion, and the white emission portion to be spaced apart from each other and a bank configured to expose the red emission portion, the green emission portion, the blue emission portion, and the white emission portion of the plurality of first electrodes.

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic plan view showing a light emitting display device according to one embodiment of the present disclosure;

FIG. 2 is a plan view showing the light emitting display device according to one embodiment of the present disclosure;

FIG. 3 is a cross-sectional view taken along line I-I′ of FIG. 2;

FIG. 4 is a cross-sectional view taken along line II-II′ of FIG. 2;

FIG. 5 is a diagram showing a circuit of one subpixel of the light emitting display device according to one embodiment of the present disclosure;

FIG. 6 is a diagram showing a light emission angle of Experimental Example 1;

FIG. 7 is a diagram showing a light emission angle of Experimental Example 2; and

FIGS. 8 and 9 are cross-sectional views showing examples of light emitting devices of light emitting display devices according to embodiments of the present disclosure.

### DETAILED DESCRIPTION

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same may obscure the subject matter of the disclosure. In addition, the names of elements used in the following description are selected in consideration of clarity of description of the disclosure, and may differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt%, or when the p-type material is present in an amount of less than 30 wt%, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, a hole transport layer and an electron transport layer.

Hereinafter, a light emitting display device according to the present disclosure will be described with reference to the accompanying drawings.

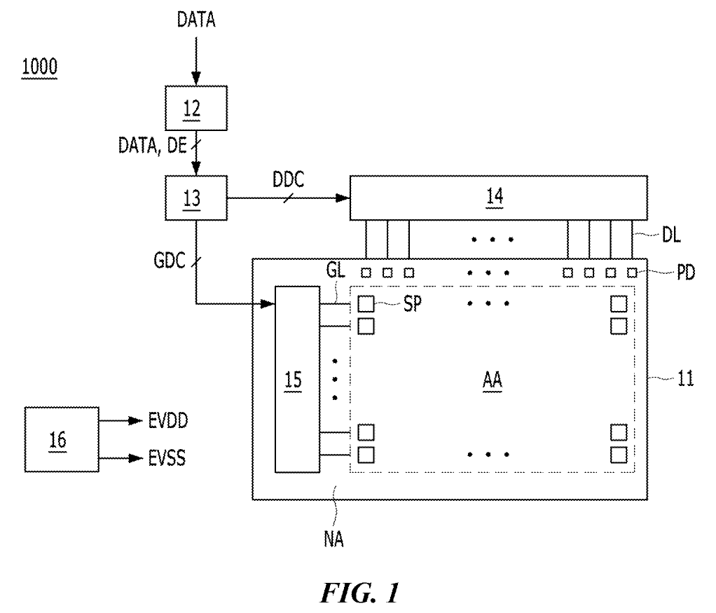

FIG. 1 is a block diagram schematically showing a light emitting display device according to one embodiment of the present disclosure.

As shown in FIG. 1, a light emitting display device 1000 according to one embodiment of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include a subpixel SP disposed at each of intersections of a plurality of gate lines GL and a plurality of data lines DL. The structure of the subpixels SP may vary depending on the type of the light emitting display device 1000.

For example, the subpixels SP may be formed in a top emission type, a bottom emission type, or a dual emission type depending on the structure thereof. The subpixels SP refer to units that may be provided with a specific type of color filter or emit their own color without a color filter. For example, the subpixels SP may include a red subpixel, a green subpixel, and a blue subpixel. Alternatively, the subpixels SP may include, for example, a red subpixel, a blue subpixel, a white subpixel, and a green subpixel. The subpixels SP may have one or more different emission areas to emit light of various colors depending on light emitting characteristics. For example, a blue subpixel and other subpixels that emit different colors from the blue subpixel may have different emission areas.

One or more subpixels SP may form one unit pixel. For example, one unit pixel may include red, green, and blue subpixels, and the red, green, and blue subpixels may be repeatedly arranged. Alternatively, one unit pixel may include red, green, blue, and white subpixels, and the red, green, blue, and white subpixels may be repeatedly arranged, or the red, green, blue, and white subpixels may be arranged in a quad type. In one embodiment according to the present disclosure, the color type, arrangement type, arrangement order, etc., of the subpixels SP may be configured in various ways depending on the light emitting characteristics, the lifespan of the elements, the specifications of the device, etc., without being limited thereto.

The display panel 11 may be divided into a display area AA (inside a dotted line) where the subpixels SP are arranged to display an image, and a non-display area NA around the display area AA. The scan driver 15 may be mounted in the non-display area NA of the display panel 11. In addition, the non-display area NA may include a pad part PAD including pad electrodes PD.

Here, the display area AA is referred to as an active area, and the non-display area NA is referred to as a non-active area.

The image processor 12 may output a data enable signal DE, and the like, in addition to the data signal DATA supplied from the outside. In addition to the data enable signal DE, the image processor 12 may output one or more of a vertical synchronization signal, a horizontal synchronization signal, and a clock signal, but these signals are omitted for convenience of explanation.

The timing controller 13 may receive the data signal DATA in addition to a driving signal from the image processor 12. The driving signal may include the data enable signal DE. Alternatively, the driving signal may include the vertical synchronization signal, the horizontal synchronization signal, and the clock signal. The timing controller 13 may output a data timing control signal DDC for controlling the operation timing of the data driver 14 and a gate timing control signal GDC for controlling the operation timing of the scan driver 15 based on the driving signal.

The data driver 14 may sample and latch the data signal DATA supplied from the timing controller 13 in response to the data timing control signal DDC supplied from the timing controller 13, convert the sampled and latched data signal into a gamma reference voltage, and output the gamma reference voltage.

The data driver 14 may output the data signal DATA through the data lines DL. The data driver 14 may be implemented in the form of an integrated circuit (IC). For example, the data driver 14 may be conductively connected to the pad electrodes PD disposed in the non-active area NA of the display panel 11 through a flexible circuit film (not shown).

The scan driver 15 may output the scan signal in response to the gate timing control signal GDC supplied from the timing controller 13. The scan driver 15 may output the scan signal through the gate lines GL. The scan driver 15 may be implemented in the form of an integrated circuit (IC) or implemented in a Gate-In-Panel (GIP) manner in the display panel 11.

The power supply 16 may output a high-potential voltage and a low-potential voltage for driving the display panel 11. The power supply 16 may supply the high-potential voltage to the display panel 11 through a first power line EVDD (a driving power line or a pixel power line), and may supply the low-potential voltage to the display panel 11 through a second power line EVSS (an auxiliary power line or a common power line).

The display panel 11 may be divided into the active area AA and the non-active area NA, and may include the plurality of subpixels SP defined by the gate lines GL and the data lines DL that intersect each other and are formed in a matrix within the active area AA.

The subpixels SP may include subpixels that emit at least two or more colors of light among red light, green light, blue light, yellow light, magenta light, and cyan light. In addition, the plurality of subpixels SP may be provided with have a specific type of color filter formed thereon, or may emit their own color without a color filter. However, the present disclosure is not limited thereto, and the color type, arrangement type, arrangement order, etc., of the subpixels SP may be configured in various ways depending on the light emitting characteristics, the lifespan of the elements, the specifications of the device, etc.

Each of the subpixels SP may include an emission portion that emits light and a non-emission portion around the emission portion.

Hereinafter, a light emitting display device to which an emission portion REM, GEM, BEM, and WEM that emits a corresponding color is applied to each of a red subpixel RSP, a green subpixel GSP, a blue subpixel BSP, and a white subpixel WSP according to one embodiment of the present disclosure will be described with reference to the drawings.

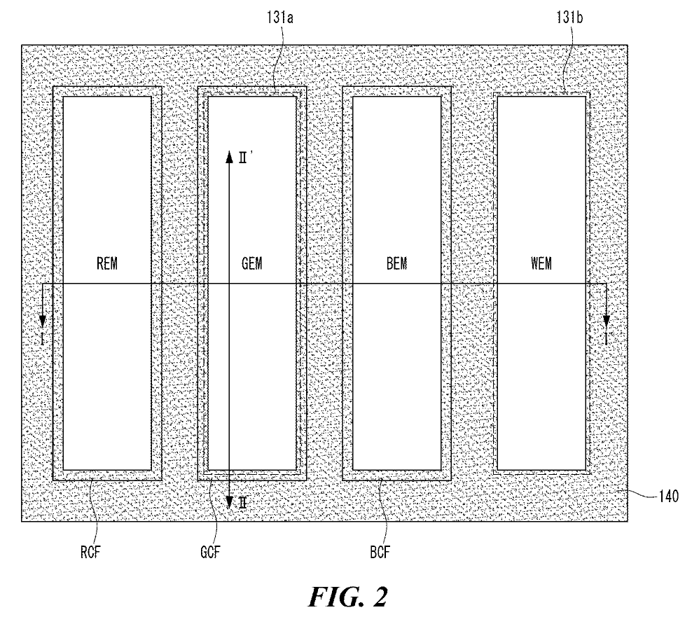

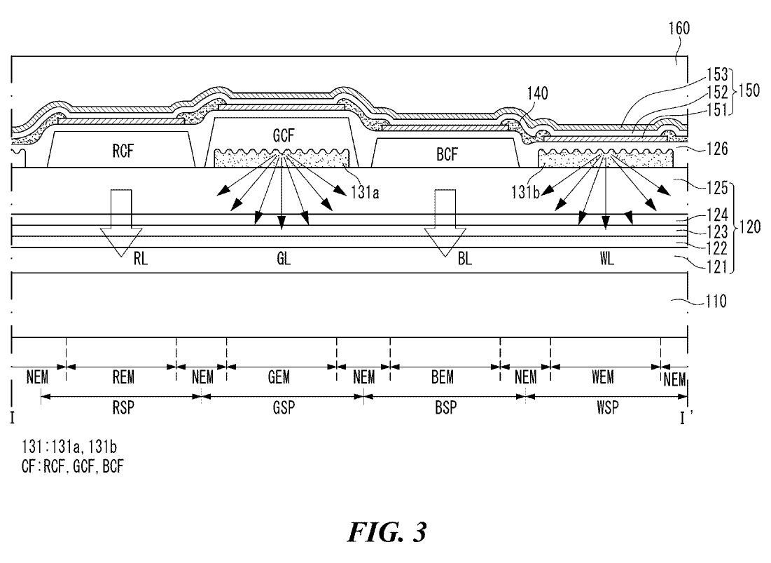

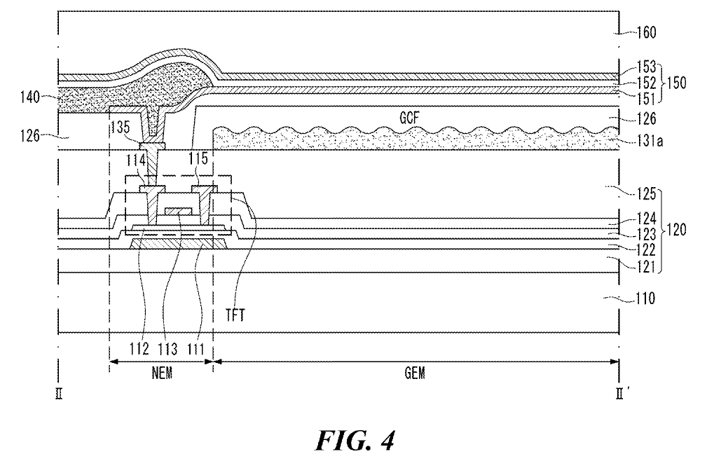

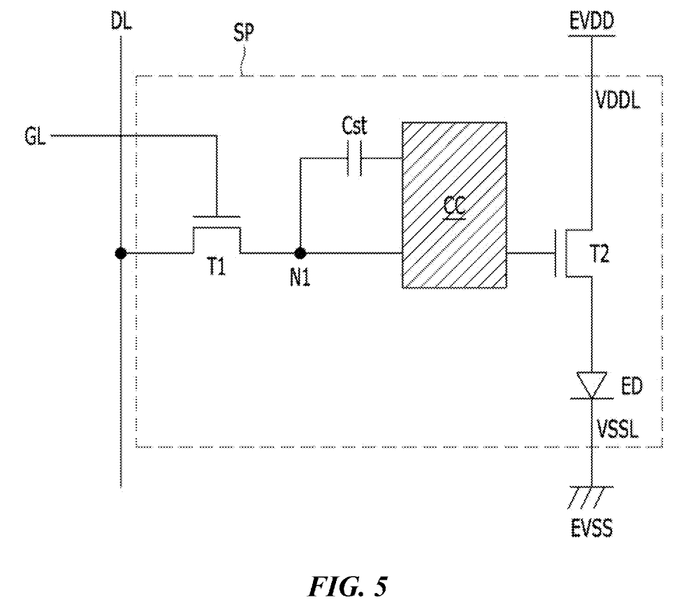

FIG. 2 is a plan view showing the light emitting display device according to one embodiment of the present disclosure, and FIG. 3 is a cross-sectional view taken along line I-I′ of FIG. 2. FIG. 4 is a cross-sectional view taken along line II-II′ of FIG. 2. FIG. 5 is a diagram showing a circuit of one subpixel of the light emitting display device according to one embodiment of the present disclosure.

The light emitting display device according to one embodiment of the present disclosure includes, as shown in FIGS. 2 to 4, a substrate 110 including a plurality of emission portions REM, GEM, BEM, and WEM, color filters CF: RCF, GCF, and BCF disposed on the substrate 110 except for the white emission portion WEM, an organic insulating layer 126 disposed on each of the emission portions REM, GEM, BEM, and WEM including the color filters CF: RCF, GCF, and BCF, and light emitting devices 150 on the organic insulating layer 126. In addition, light emitting display device includes scattering patterns 131: 131a and 131b between the substrate 110 and the color filter GCF and between the substrate 110 and the organic insulating layer 126 in the green emission portion GEM and the white emission portion.

More specifically, the red emission portion REM, the green emission portion GEM, the blue emission portion BEM, and the white emission portion WEM are areas spaced apart from each other on the substrate 110 and correspond to open areas of a bank 140. The bank 140 is disposed in the non-emission portions NEM between the red emission portion REM, the green emission portion GEM, the blue emission portion BEM, and the white emission portion WEM that are spaced apart from each other.

Each subpixel RSP, GSP, BSP, or WSP includes the emission portion REM, GEM, BEM, or WEM and the non-emission portion NEM surrounding the emission portion REM, GEM, BEM, and WEM.

The light emitting device 150 includes a first electrode 151, an intermediate layer 152, and a second electrode 153.

A plurality of first electrodes 151 is provided on the organic insulating layer 126 on the substrate 110. The plurality of first electrodes 151 is spaced apart from each other to be provided in the respective subpixels RSP, GSP, BSP, and WSP. In contrast to the plurality of first electrodes 151, the intermediate layer 152 and the second electrode 153, which are other components of the light emitting device 150, may be provided in common in the plurality of subpixels.

The intermediate layer 152 may emit white light and include a plurality of organic layers. The intermediate layer 152 may include one or more emission stacks. For example, the intermediate layer 152 may include a hole transport layer, one or more emission layers to emit light of at least one color, and an electron transport layer in each emission stack. Each of the hole transport layer, the emission layer, and the electron transport layer may be an organic layer including an organic material independently. When the intermediate layer 152 includes a plurality of emission stacks, a charge generation layer may be provided between adjacent emission stacks.

Since the intermediate layer 152 has a plurality of layers in common in the plurality of subpixels RSP, GSP, BSP, and WSP provided in the active area AA of the substrate 110, there are advantages of omitting use of depositions mask having micro-openings, and improving the manufacturing yield of light emitting display devices due to no yield reduction due to misalignment of the deposition masks for the respective layers. Since the intermediate layer 152 emits white light, in order to achieve individual color expression in the respective subpixels RSP, GSP, BSP, as shown in FIGS. 2 and 3, a red color filter RCF that selectively emits light having red wavelengths is disposed in the red subpixel RSP, a green color filter GCF that selectively emits light having green wavelengths is disposed in the green subpixel GSP, and a blue color filter BSP that selectively emits light having blue wavelengths is disposed in the blue subpixel BSP.

In each subpixel RSP, GSP, BSP, or WSP, the first electrode 151 of the light emitting device 150 is conductively connected to a thin film transistor TFT, so that the light emitting device 150 of each subpixel RSP, GSP, BSP, or WSP is able to be driven independently.

The bank 140 may overlap the edge of the first electrodes 151 of the light emitting devices 150, and expose the emission portion REM, GEM, BEM, or WEM of the first electrode 151 in each subpixel RSP, GSP, BSP, or WSP.

In the light emitting display device of the embodiments of the present disclosure, a first scattering pattern 131a is provided between the substrate 110 and the green color filter GCF in the green emission portion GEM, and a second scattering pattern 131b is provided between a substrate 110 and the organic insulating layer 126 in the white emission portion WEM.

The upper surface of the organic insulating layer 126 becomes a surface on which the first electrode 151 of the light emitting device 150 is formed in each subpixel RSP, GSP, BSP, or WSP, and the organic insulating layer 126 includes a transparent organic insulating material. The organic insulating layer 126 may include an overcoat material.

Each of the first and second scattering patterns 131a and 131b has a randomly sized wrinkle pattern on the upper surface thereof.

Each of the first scattering pattern 131a and the second scattering pattern 131b may have a plurality of curved planes, the upper surfaces of which protrude toward the organic insulating layer 126. The heights of the plurality of curved planes may be different, and the plurality of curved planes is randomly arranged without certain periodicity. Therefore, light incident on the first and second scattering patterns 131a and 131b does not have dependency on specific wavelengths due to the structure of the first and second scattering patterns 131a and 131b. As shown in FIG. 3, the first and second scattering patterns 131a and 131b may cause light incident thereon to be scattered not only vertically but also at multiple angles due to the wrinkle pattern or the plurality of curved planes formed on the upper surfaces of the first and second scattering patterns 131a and 131b, thereby being capable of widening a light emission distribution.

In the white emission portion WEM, white light having passed through the light emitting device 150 is incident on the second scattering pattern 131b through the organic insulating layer 126, and the light incident on the second scattering pattern 131b is scattered radially at multiple angles from the upper surface of the second scattering pattern 131b, passes through the second scattering pattern 131b, a plurality of insulating layers 120, and the substrate 110, and is emitted as scattered white light WL.

In the green emission portion GEM, white light having passed through the light emitting device 150 and traveling downward passes through the organic insulating layer 126 and the green color filter GCF to be selectively emitted as green light and is incident on the first scattering pattern 131a from the green color filter CGF, and the green light incident on the first scattering pattern 131a is scattered radially at multiple angles from the upper surface of the first scattering pattern 131a, passes through the first scattering pattern 131a, the plurality of insulating layers 120, and the substrate 110, and is emitted as scattered green light GL.

In the red emission portion REM and the blue emission portion BEM that do not have the first and second scattering patterns 131a and 131b, white light having passed through the light emitting devices 150 and traveling downward passes through the organic insulating layer 126, the red color filter RCF and the blue color filter BCF, the plurality of insulating layers 120 and the substrate 110, and is emitted as red light RL and blue light BL with a large light emission amount in the vertical direction.

The first and second scattering patterns 131a and 131b are provided so that luminous efficacy of white light and a light emission distribution area are increased, and thus, a luminance deviation depending on changes in viewing angles may be reduced when the light emitting display device is observed at different viewing angles.

The light emitting display device according to one embodiment of the present disclosure has the scattering patterns 131: 131a and 131b disposed not only in the white emission portion WEM but also in the green emission portion GEM. Since a luminance viewing angle is evaluated in white display, the white emission portion WEM is provided with the second scattering pattern 131b. In addition, in terms of the luminance efficiency of the light emitting display device, since the luminance contribution of the green emission portion GEM is higher than those of the red emission portion REM and the blue emission portion BEM, the luminance characteristic of the green emission portion GEM dominantly affects the luminance characteristic of the light emitting display device. Therefore, the light emitting display device according to one embodiment of the present disclosure is provided with the first scattering pattern 131a in the green emission portion GEM among the red, green, and blue emission portions REM, GEM, and BEM to improve the luminous efficacy of the green emission portion GEM, thus providing luminance enhancement efficiency during white display.

When the light emitting display device including the light emitting devices 150 having the intermediate layer 152 including the plurality of emission stacks does not have a scattering pattern, a half luminance angle, i.e., an angle where the luminance drops to half of frontal luminance, is a viewing angle of approximately 50° to 60°. When the light emitting display device of the present disclosure has the first and second scattering patterns 131a and 131b in the green emission portion GEM and the white emission portion WEM, the half luminance angle may be improved by diversifying luminous efficacy and a light emission distribution by the first and second scattering patterns 131a and 131b in changes in viewing angle, and more particularly, the half luminance angle may be improved by approximately 10° or more compared to a structure having no scattering pattern.

The upper surface of the first scattering pattern 131a is in contact with the green color filter GCF. The upper surface of the second scattering pattern 131b is in contact with the organic insulating layer 126. Therefore, the vertical phases of the light emitting devices 150 disposed on the organic insulating layer 126 in the green emission portion GEM and the white emission portion WEM may be different.

The upper surface of the green color filter GCF overlapping the first scattering pattern 131a and the upper surface of the organic insulating layer 126 overlapping the second scattering pattern 131b may be flat, respectively.

The first scattering pattern 131a and the second scattering pattern 131b have the same vertical phase on the substrate 110. FIG. 3 shows an example in which the first and second scattering patterns 131a and 131b are located on the upper surface of the same insulating layer 120.

A pixel circuit may be provided in each subpixel SP: RSP, GSP, BSP, or WSP of the substrate 110. FIG. 5 illustrates one example of the pixel circuit, which will be described later.

The pixel circuit is further provided between the substrate 110 and the organic insulating layer 126, and the pixel circuit overlaps the bank 140 and is disposed in the non-emission portion NEM so as not to hinder light emission in the emission portions REM, GEM, BEM, and WEM.

The pixel circuit may include the transistor TFT conductively connected to the first electrode 151 of the light emitting device 150. As shown in FIG. 4, the transistor TFT may be disposed in the non-emission portion NEM and include an active layer 112, a gate electrode 113 overlapping a channel region of the active layer 112, and a first source/drain electrode 114 and a second source/drain electrode 115 connected to both sides of the active layer 112.

In addition, the first source/drain electrode 114 may be connected to the first electrode 151 of the light emitting device 150 through a connection electrode 135. In some cases, the connection electrode 135 may be omitted so that the first source/drain electrode 114 may be directly connected to the first electrode 151 of the light emitting device 150.

A light shielding pattern 111 may be further provided below the active layer 112 to prevent the active layer 112 from being affected by light entering from below the substrate 110.

The insulating layers 120 may include first to fifth insulating layers 121, 122, 123, 124, and 125 sequentially disposed on the substrate 110. The first insulating layer 121 may function as a buffer layer that prevents impurities of the substrate 110 from penetrating components, such as the transistor TFT, wiring, or the light emitting device 150, provided on the upper surface of the substrate 110. The second insulating layer 122 may be disposed between the light shielding pattern 111 and the active layer 112 and function as a buffer layer or an interlayer insulating layer. The third insulating layer 123 may be disposed between the active layer 112 and the gate electrode 113 and may function as a gate insulating layer. The fourth insulating layer 124 may function as an interlayer insulating layer located between the gate electrode 113 and the first and second source/drain electrodes 114 and 115.

The fifth insulating layer 125 covering the transistor TFT including the first and second source/drain electrodes 114 and 115 may function as a protective layer. The fifth insulating layer 125 may also be referred to as a planarization layer.

The organic insulating layer 126 and the fifth insulating layer 125 may include an organic insulating material. In some cases, the organic insulating layer 126 and the fifth insulating layer 125 may be formed of the same organic insulating material. At least the first scattering pattern 131a is disposed in an area greater than or equal to the green emission portion GEM and partially overlap the non-emission portion NEM surrounding the green emission portion GEM. The second scattering pattern 131b is disposed in an area greater than or equal to the white emission portion WEM.

The green color filter GCF disposed on the first scattering pattern 131a is provided in a greater area than the first scattering pattern 131a, so that at least the upper surface of the first scattering pattern 131a having wrinkles or a plurality of curved portions has an interface that is in contact with the green color filter GCF as a whole. As shown in FIGS. 2 and 4, the green color filter GCF may be disposed in a larger area than the first scattering pattern 131a and have an edge covering the side surface of the first scattering pattern 131a in the non-emission portion NEM.

The first electrode 151 in the green emission portion GEM is provided with the first scattering pattern 131a formed therebelow, and thus has a higher vertical phase than the first electrodes 151 in the red emission portion REM and the blue emission portion BEM.

In addition, the first electrode 151 in the white emission portion WEM may have a lower vertical phase than the first electrodes 151 in the red emission portion REM, the green emission portion GEM, and the blue emission portion BEM, because a color filter RCF, GCF, or BCF is not disposed in the white emission portion WEM unlike the red emission portion REM, the green emission portion GEM, and the blue emission portion BEM.

Referring to FIG. 3, the thicknesses of the color filters RCF, GCF, and BCF are greater than the thicknesses of the first and second scattering patterns 131: 131a and 131b. The thicknesses of the color filters RCF, GCF, and BCF are approximately 1.1 μm to 3 μm. The thicknesses of the first and second scattering patterns 131a and 131b are 0.5 μm to 1.0 μm.

In the respective emission portions REM, GEM, BEM, and WEM, since there is a difference in whether the color filter RCF, GCF, or BCF is provided and whether the first or second scattering pattern 131a or 131b is provided, a thickness between the insulating layers 120 and the organic insulating layer 126 is different, and the vertical phase of the first electrode 151 from the upper surface of the organic insulating layer 126 formed by reflecting a step caused by the lower configuration is different. Accordingly, the vertical phase of the first electrode 151 disposed on the organic insulating layer 126 in each emission portion REM, GEM, BEM, or WEM is different. Approximately, the vertical phase of the first electrode 151 is the highest in the green emission portion GEM, and then decreases in the order of the red emission portion REM, the blue emission portion BEM, and the white emission portion WEM. The reason why there is a difference in vertical phase of the first electrode 151 between the red emission portion REM and the blue emission portion BEM is that the color filter (RCF>BCF) transmitting long wavelengths may be thicker than the other color filter (RCF>BCF). However, this is only an example, and the thickness difference between the red color filter RCF and the blue color filter BCF may be minimal or negligible.

In the light emitting display device according to the embodiments of the present disclosure, the red emission portion REM or the blue emission portion BEM having a difference in vertical phase from each of the green emission portion GEM and the white emission portion WEM is disposed between the green emission portion GEM having the first electrode 151 having the highest vertical phase and the white emission portion WEM having the first electrode 151 having the lowest vertical phase, rather than the difference in thickness between the red color filter RCF and the blue color filter BCF, so that the bank 140 is disposed to pass through inclined planes of the upper surface of the organic insulating layer 126 having different vertical phases between adjacent emission portions REM, GEM, BEM, and WEM, thereby increasing a surface area occupied by the bank 140 compared to the surface area of the non-emission portions NEM of the substrate 110.

In the same manner as the organic insulating layer 126 having the upper surface formed by reflecting the step caused by the lower configuration, the bank 140 is also formed by reflecting the step caused by the lower configuration like the organic insulating layer 126.

The intermediate layer 152 of the light emitting device 150 has a continuous configuration without interruption in the plurality of subpixels RSP, GSP, BSP, and WSP. Therefore, the intermediate layer 152 is continuously disposed not only on the emission portions REM, GEM, BEM, and WEM but also on the bank 140. In this case, the intermediate layer 152 disposed on the increased surface area of the bank 140 between adjacent emission portions REM, GEM, BEM, and WEM increases resistance between the adjacent long emission portions REM, GEM, BEM, and WEM. Therefore, when a predetermined emission portion REM, GEM, BEM, or WEM emits light, a path of leakage current increases in an adjacent emission portion with the bank 140 interposed between the emission portions due to the increased surface area of the bank 140, thereby preventing or significantly reducing leakage light emission.

The light emitting display device according to the embodiments of the present disclosure has a structure in which the intermediate layer 152 is provided in common in the subpixels RSP, GSP, BSP, and WSP. Therefore, the intermediate layer 152 is disposed without distinction between the respective subpixels RSP, GSP, BSP, and WSP, so that the yield of a deposition process is excellent and the deposition efficiency of each layer is excellent. However, in a structure in which an intermediate layer is provided in common in subpixels, when a bank is disposed between subpixels of the same vertical phase, leakage current between adjacent subpixels may be large due to a layer with high mobility among the intermediate layer disposed on the bank. However, in the light emitting display device according to one embodiment of the present disclosure, the vertical phase of the upper surface of the vertical organic insulating layer 126 is different in the respective emission portions REM, GEM, BEM, and WEM of adjacent subpixels, and the bank 140 disposed on the organic insulating layer 126 having different vertical phases is disposed by reflecting the step caused by the different vertical phases of the upper surface of the organic insulating layer 126. The intermediate layer 152 disposed on the bank 140 is also disposed on the upper surface of the bank 140 between two adjacent subpixels having different heights, so that even if the intermediate layer 152 is disposed in common between the adjacent subpixels, the intermediate layer 152 has an extended path between adjacent subpixels RSP-GSP, GSP-BSP, BSP-WSP, or WSP-RSP, and thus, the resistance increases in the flow of leakage current, and light emission of a designated subpixel does not cause leakage light emission of an adjacent subpixel or has a minimal effect.

Particularly, leakage current is generated by low-grayscale light emission, and in the light emitting display device according to the embodiments of the present disclosure, the bank 140 having an increased surface area may be provided to eliminate low-grayscale leakage light emission.

In addition, the light emitting display device according to one embodiment of the present disclosure may effectively prevent lateral leakage current due to the intermediate layer 152 provided in common in adjacent subpixels.

The first electrode 151 of each of the red emission portion REM, the green emission portion GEM, the blue emission portion BEM, and the white emission portion WEM may be in contact with the flat upper surface of the organic insulating layer 126. As described above, the upper surface of the organic insulating layer 126 in the emission portions REM, GEM, BEM, and WEM is flat, but the vertical phase of the upper surface of the organic insulating layer 126 in the emission portions REM, GEM, BEM, and WEM is different. Due to the difference in the vertical phase, the bank 140 is disposed with a wider surface area than the non-emission portion on the substrate 110, thereby increasing the path of common layers disposed on the bank 140 on the adjacent subpixels.

The maximum thickness of the first scattering pattern 131a may be less than the thickness of the green color filter GCF. The maximum thickness of the first scattering pattern 131a means a vertical distance from an interface where the first scattering pattern 131a comes into contact with the upper surface of the insulating layers 120 to a part of the first scattering pattern 131a protruding most upwardly toward the organic insulating layer 126. The maximum thickness of the first scattering pattern 131a is 0.5 μm to 1.0 μm, and is less than the thickness of the green color filter GCF, which is 1.2 μm to 3.0 μm.

Surface roughness of the first scattering pattern 131a is not exposed from the green color filter GCF, and the upper surface of the green color filter GCF may be flat.

The first scattering pattern 131a and the second scattering pattern 131b may be formed of the same material through the same patterning process. The first and second scattering patterns 131a and 131b are formed by spin-coating a liquid resin material on the upper surface of the insulating layers 120, irradiating the resin material with ultraviolet light to form a wrinkle pattern on the upper surface of the resin material and solidifying the same, and then performing selective patterning so that the solidified resin material remains in the green emission portion GEM and the white emission portion WEM. During the patterning process, the resin material is removed from the red and blue emission portions REM and BEM except for the green emission portion GEM and the white emission portion WEM and parts of the non-emission portions NEM around the green emission portion GEM and the white emission portion WEM.

The size of the wrinkle patterns left on the upper surfaces of the first and second scattering patterns 131a and 131b and the shape of the wrinkle patterns may be changed depending on an energy intensity and time of UV irradiation.

The first and second scattering patterns 131a and 131b have a transmittance of 90% or more for light in the visible spectrum to have a function of assisting in light scattering in the traveling direction of light, and do not hinder transmission of green light having passed through the green color filter GCF in the green emission portion GEM or transmission of white light having passing through the light emitting device 150 in the white emission portion WEM.

The refractive index of the first and second scattering patterns 131a and 131b may be lower than the refractive indices of the green color filter GCF and the organic insulating layer 126, respectively.

The maximum thicknesses of the first and second scattering patterns 131a and 131b may be less than the maximum thickness of the organic insulating layer 126.

The organic insulating layer 126 is formed by disposing the color filters RCF, GCF, and BCF in the red, green, and blue subpixels RSP, GSP, and BSP, spin-coating a material, and then firing the material to solidify the same. Here, the maximum thickness of the organic insulating layer 126 may be observed in the non-emission portion NEM surrounding the green color filter GCF in the green subpixel GSP.

The refractive index of the first scattering pattern 131a may be lower than the refractive index of the green color filter GCF, and the refractive index of the second scattering pattern 131b may be lower than the refractive index of the organic insulating layer 126. Light passing through the first scattering pattern 131a from the green color filter GCF is scattered radially from the upper surface of the first scattering pattern 131a, and light passing through the second scattering pattern 131b from the organic insulating layer 126 is scattered radially from the upper surface of the second scattering pattern 131b.

The upper surface of the organic insulating layer 126 has a curved plane in which the vertical phase changes in an area surrounding the green emission portion GEM, and a curved plane in which the vertical phase changes in an area surrounding the white emission portion WEM, and the bank 140 may be disposed on the curved planes in the non-emission portion around the green emission portion GEM and the non-emission portion around the white emission portion WEM, respectively.

The curved plane of the upper surface of the organic insulating layer 126 around the green emission portion GEM may be located between the green emission portion GEM and the red emission portion REM, and between the green emission portion GEM and the blue emission portion BEM. In addition, the curved plane of the upper surface of the organic insulating layer 126 around the white emission portion WEM may be located between the white emission portion WEM and the blue emission portion BEM, and between the white emission portion WEM and the red emission portion REM. The curved plane of the upper surface of the organic insulating layer 126 increases the paths of the bank 140 and the intermediate layer 152 sequentially formed thereon, so that the intermediate layer 152 may increase resistance to the leakage current in adjacent subpixels and eliminate the influence of the leakage current between the adjacent subpixels.

Here, the first electrode 151 in the green emission portion GEM is disposed in contact with the flat upper surface of the organic insulating layer 126 having a first vertical distance from the substrate 110, and the first electrode 151 in the white emission portion WEM is disposed in contact with the flat upper surface of the organic insulating layer 126 having a second vertical distance smaller than the first vertical distance from the substrate 110. The first electrodes in the red emission portion REM and the blue emission portion BEM are disposed in contact with the flat upper surface of the organic insulating layer 126 between the first vertical distance and the second vertical distance from the substrate 110.

The intermediate layer 152 may be disposed on the upper surface of the first electrode 151 in each of the red emission portion REM, the green emission portion GEM, the blue emission portion BEM, and the white emission portion WEM, and on the upper surface of the bank 140.

As shown in FIG. 5, each subpixel SP: RSP, WSP, BSP, or WSP in the active area AA may include, for example, a first transistor T1, a second transistor T2, a storage capacitor Cst, a compensation circuit CC, and the light emitting device ED (150 in FIGS. 3 and 4).

For example, the first transistor T1 may be a switching transistor, and the second transistor T2 may be a driving transistor.

A first source/drain electrode (e.g., a drain electrode) of the first transistor T1 is conductively connected to a data line DL, and a second source/drain electrode (e.g., a source electrode) of the first transistor T1 is conductively connected to a first node N1. A gate electrode of the first transistor T1 is conductively connected to a gate line GL. The first transistor T1 transmits a data signal supplied through the data line DL to the first node N1 in response to a scan signal supplied through the gate line GL.

The storage capacitor Cst is conductively connected to the first node N1 and charges the first node N1 with an applied voltage.

A first source/drain electrode (e.g., a drain electrode) of the second transistor T2 receives a high-voltage power supply voltage EVDD as a high-potential driving voltage through a driving voltage line VDDL, and a second source/drain electrode (e.g., a source electrode) of the second transistor T2 is conductively connected to a first electrode (e.g., an anode AND) of the light emitting device ED. The second transistor T2 may control the amount of driving current flowing to the light emitting device ED in response to voltage applied to a gate electrode.

The semiconductor layer of the first transistor T1 or/and the second transistor T2 may include silicon, such as amorphous silicon (a-Si), polycrystalline silicon (poly-Si), or low-temperature polycrystalline silicon (poly-Si), or may include an oxide, such as indium-gallium-zinc-oxide (IGZO), but is not limited thereto. At least one of the first transistor T1 or the second transistors T2 may include an oxide semiconductor layer, and may thus be formed at a relatively low temperature compared to other materials, maintain amorphous characteristics, and have high mobility.

The light emitting device ED (150 of FIGS. 3 and 4) outputs light corresponding to the driving current. The light emitting device ED may output light corresponding to any one color of red, green, blue, and white.

The light emitting device (ED) 150 may include the first electrode 151, the intermediate layer 152 disposed on the first electrode 151, and the second electrode 153 that supplies a common voltage. The intermediate layer 152 may include a plurality of common layers and one or more emission layers.

The second electrode 153 of the light emitting device (ED) 150 receives a low-potential voltage EVSS or a ground voltage through a low-potential voltage line VSSL. The low-potential voltage line VSSL may be disposed and included in the non-active area NA. In some cases, the low-potential voltage line VSSL may also be disposed in the active area AA to prevent unevenness of the low-potential voltage EVSS generated in the active area AA. The low-potential voltage EVSS is also referred to as a common voltage.

The compensation circuit CC may be provided in the subpixel SP to compensate the threshold voltage of the second transistor T2, etc. The compensation circuit CC may be composed of one or more transistors. The compensation circuit CC may include one or more transistors and capacitors, and may be configured in various ways depending on a compensation method. The subpixel SP including the compensation circuit CC may include circuits of various structures having different numbers of transistors and/or capacitors, such as 3T1C, 4T2C, 5T2C, 6T1C, 6T2C, 7T1C, and 7T2C.

Meanwhile, the pixel circuit of the subpixel SP illustrated in FIG. 5 may be provided in each subpixel SP. The transistor TFT illustrated in FIG. 4 may be, for example, the second transistor T2 of FIG. 5. However, the embodiments of the present disclosure are not limited thereto, and the transistor connected to the light emitting device 150 may be a transistor that receives a light emitting control signal. FIG. 5 is an example of the pixel circuit of the subpixel, and the subpixel SP: RSP, GSP, BSP, or WSP may further include other transistors and/or capacitors.

The unexplained configuration of the light emitting display device of the present disclosure will now be described.

The substrate 110 may include at least one of a glass substrate, a plastic film, and a metal plate having a designated supporting force. The substrate 110 may be formed of a flexible material. For example, when the substrate 110 is formed of a plurality of layers, the substrate 110 may have a stacked structure of a first organic layer, an inorganic insulating layer, and a second organic layer. The first organic layer provided as the outermost layer may prevent introduction of external impurities and have a protective function. The second organic layer may enable flattening of a surface on which an internal array structure is formed and prevent charge transfer or impurity transfer from the outside to the inside of the substrate 110. The inorganic insulating layer between the first and second organic layers may have a function of preventing moisture diffusion between the first and second organic layers and movement of conductive impurities toward the second organic layer.

The subpixels RSP, GSP, BSP, and WSP described herein mean a plurality of divided areas arranged within the active area AA on the substrate 110. Each of the subpixels RSP, GSP, BSP, and WSP includes the emission portion REM, WEM, BEM, or GEM and the non-emission portion around the emission portion REM, WEM, BEM, or GEM.

The non-emission portions are defined by the bank 140 that defines the emission portions REM, WEM, BEM, and GEM of the subpixels. The bank 140 is disposed in the non-emission portions so as to expose the emission portions REM, WEM, BEM, and GEM of the first electrodes 151 disposed in the respective subpixels RSP, GSP, BSP, and WSP. The bank 140 is disposed to cover the edge of each of the first electrodes 151. The bank 140 has openings corresponding to the emission portions REM, WEM, BEM, and GEM.

The bank 140 may be formed of a transparent or opaque organic material. When the bank 140 includes an opaque organic material, the bank 140 may include a light shielding organic material that absorbs or blocks at least some wavelengths in the visible spectrum. The light shielding organic material of the bank 140 includes a light absorbing material that absorbs at least some wavelengths in the visible spectrum. The bank 140 may include a material, such as carbon black or a color pigment. The bank 140 may be formed by stacking a light shielding organic material layer and a light transmitting organic material layer, or may be formed of a light transmitting organic material layer as a single layer.

The light emitting display device has a circuit configuration including a plurality of transistors TFTs and one or more storage capacitors in each subpixel RSP, GSP, BSP, or WSP on the substrate 110, and each subpixel RSP, GSP, BSP, or WSP may be selectively driven. As an example, FIG. 4 shows one transistor TFT in each subpixel SP: RSP, GSP, BSP, or WSP, but the subpixel SP: RSP, GSP, BSP, or WSP may include two or more transistors as needed. The pixel circuit of each subpixel RSP, GSP, BSP, or WSP may include one or more switching transistors that control whether to turn on the corresponding subpixel RSP, GSP, BSP, or WSP, and a driving transistor that supplies a driving current to the light emitting device 150.

The light shielding pattern 111 may be further provided below the transistor TFT to prevent the active layer 112 from being affected by light entering through the substrate 110. It is desirable that the light shielding pattern 111 be formed with a greater area than the channel region of the active layer 112. In some cases, the light shielding pattern 111 may be omitted.

The insulating layers 120 including the plurality of insulating layers 121, 122, 123, 124, and 125 are disposed on the substrate 110, and the color filters CF: RCF, GCF, and BCF including the first and second scattering patterns 131a and 131b may be provided on the insulating layers 120.

The first insulating layer 121 may function as a buffer layer or an active buffer layer. The buffer layer and the active buffer layer may prevent impurities from being transferred upwards from below the wiring included in the internal array or the active layer, and support and protect upper components. The first insulating layer 121 may include a plurality of layers.

The transistor TFT and the storage capacitor may be disposed on the first insulating layer 121 in each subpixel RSP, GSP, BSP, or WSP.

The light shielding pattern 111 that prevents light from being transmitted to the active layer 112 of the transistor TFT from below may be provided on the first insulating layer 121.

The second insulating layer 122 for insulation may be disposed between the light shielding pattern 111 and the active layer 112.

The transistor TFT may be disposed on the second insulating layer 122 in each of the plurality of subpixels. For example, the transistor TFT may include the active layer 112, the gate electrode 113 overlapping the active layer 112 with the third insulating layer 123 interposed therebetween, and the first source/drain electrode 114 and the second source/drain electrode 115 connected to both sides of the active layer 112.

As an example, the storage capacitor may include a first storage electrode and a second storage electrode overlapping each other. At least one of the first storage electrode or the second storage electrode may include the same material as the active layer 112, and the other may include the same material as at least one of the gate electrode 113, the first and second source/drain electrodes 114 and 115, or the light shielding pattern 111.

The third insulating layer 123 between the active layer 112 and the gate electrode 113 may function as a gate insulating layer.

The active layer 112 may include, for example, a silicon-based or oxide semiconductor. The silicon-based semiconductor may include crystalline and/or amorphous silicon. The oxide semiconductor may include at least one of gallium oxide, tin oxide, zinc oxide, indium oxide, iron oxide, or indium-gallium-zinc oxide. In some cases, the oxide semiconductor layer may be formed as a plurality of layers formed of different materials or having different material composition ratios. Each subpixel may include a plurality of thin film transistors, and the thin film transistors may be located on different layers. For example, each subpixel of the substrate 110 may include a plurality of thin film transistors having different active layers. For example, a first thin film transistor may have a silicon-based active layer and be located closer to the substrate 110, and a second thin film transistor may have an oxide semiconductor-based active layer and be disposed above the first thin film transistor.

The active layer 112 may include the channel region overlapping the gate electrode 113, and source/drain regions connected to the first and second source/drain electrodes 114 and 115, respectively.

The third insulating layer 123 may be selectively disposed to correspond to the channel region of the active layer 112, or may be provided on the entire surface of the substrate 110 except for regions which the first and second source/drain electrodes 114 and 115 penetrate. The third insulating layer 123 may perform a function of insulating between the active layer 112 and the gate electrode 113. The third insulating layer 123 may be formed of an inorganic insulating material, and may be, for example, a silicon oxide (SiOₓ) layer, a silicon nitride (SiNₓ) layer, a silicon oxynitride (SiOₓN_{y}) layer, or a multilayer layer thereof.

The gate electrode 113 may be formed on the third insulating layer 123. The gate electrode 113 may be disposed to face the active layer 112 with the third insulating layer 123 interposed therebetween.

The fourth insulating layer 124 may be formed on the gate electrode 113 to cover the gate electrode 113 and protect the gate electrode 113. In addition, the fourth insulating layer 124 may perform a function of protecting at least one electrode of the thin film transistor TFT, for example, the gate electrode 113 and the active layer 112. The fourth insulating layer 124 may be formed of an inorganic insulating material. For example, the fourth insulating layer 124 may be, for example, a silicon oxide (SiOₓ) layer, a silicon nitride (SiNₓ) layer, a silicon oxynitride (SiOₓN_{y}) layer, or a multilayer layer thereof.

The first source/drain electrode 114 and the second source/drain electrode 115 may be disposed on the fourth insulating layer 124. The fourth insulating layer 124 and the third insulating layer 123 have contact holes to allow the first and second source/drain electrodes 114 and 115 to come into contact with both ends of the active layer 112, respectively, by removing corresponding areas.

Each of the gate electrode 113 and the first and second source/drain electrodes 114 and 115 may be formed as a single layer or multiple layers.

When the gate electrode 113 and the first and second source/drain electrodes 114 and 115 are formed as a single layer, the gate electrode 113 and the first and second source/drain electrodes 114 and 115 may be formed of one selected from the group consisting of molybdenum (Mo), aluminum (Al), chromium (Cr), gold (Au), titanium (Ti), nickel (Ni), neodymium (Nd), copper (Cu), and alloys thereof. In addition, when the gate electrode 113 and the first and second source drain electrodes 114 and 115 are formed as multiple layers, the gate electrode 113 and the first and second source drain electrodes 114 and 115 may be formed as double layers of molybdenum/aluminum-neodymium, molybdenum/aluminum, titanium/aluminum, or copper/molybdenum-titanium. Alternatively, the gate electrode 113 and the first and second source drain electrodes 114 and 115 may be formed as triple layers of molybdenum/aluminum-neodymium/molybdenum, molybdenum/aluminum/molybdenum, titanium/aluminum/titanium, or molybdenum-titanium/copper/molybdenum-titanium.

However, the gate electrode 113 and the first and second source electrodes 114 and 115 are not limited thereto, and the gate electrode 113 and the first and second source electrodes 114 and 115 may be formed as multiple layers formed of one selected from the group consisting of molybdenum (Mo), aluminum (Al), chromium (Cr), gold (Au), titanium (Ti), nickel (Ni), neodymium (Nd), copper (Cu), and alloys thereof.

The fifth insulating layer 125 that protects the transistor TFT may be further provided on the transistor TFT. The fifth insulating layer 125 may be disposed as an inorganic insulating layer or an organic insulating layer. In some cases, the fifth insulating layer 125 may be omitted.

When the fifth insulating layer 125 is provided, the fifth insulating layer 125 may have a contact hole exposing the first source/drain electrode 114. Through the contact hole provided in the fifth insulating layer 125, the first source/drain electrode 114 of the transistor TFT may be connected to the connection electrode 135 provided on the fifth insulating layer 125.

Each of the first to fourth insulating layers 121, 122, 123, and 124 may be formed of an inorganic insulating layer. The inorganic insulating layer may be, for example, at least one of a silicon oxide layer, a silicon nitride layer, or a silicon oxynitride layer.

The first and second scattering patterns 131a and 131b may be disposed on the fifth insulating layer 125, and may be disposed in the green emission portion GEM and the white emission portion WEM, respectively. The winkle pattern is formed on the upper surfaces of the first and second scattering patterns 131a and 131b by spin-coating a transparent resin material and then irradiating the resin material with ultraviolet light.

The size and shape of wrinkles disposed on the upper surfaces of the first and second scattering patterns 131a and 131b may be controlled by the energy intensity and time/speed of the ultraviolet irradiation process. In addition, patterning of the first and second scattering patterns 131a and 131b is performed through a photolithography process, and is advantageous for manufacturing a large-area light emitting display device.

The red color filter RCF, the green color filter GCF, and the blue color filter BCF may be provided on the fifth insulating layer 125 corresponding to the red subpixel RSP, the green subpixel GSP, and the blue subpixel BSP. The red color filter RCF may include a color pigment that selectively transmits red light, the green color filter GCF may include a color pigment that selectively transmits green light, and the blue color filter BCF may include a color pigment that selectively transmits blue light. Here, the green color filter GCF is provided on the green emission portion GEM to cover the first scattering pattern 131a and have a greater thickness than the thickness of the first scattering pattern 131a.

Each of the red, blue, and green color filters RCF, BCF, and GCF is formed of an organic insulating material and has properties of selectively transmitting predetermined wavelengths and absorbing and shielding the remaining wavelengths. In addition, the red, blue, and green color filters RCF, BCF, and GCF include materials having a higher refractive index than the first and second scattering patterns 131a and 131b.

In addition, the organic insulating layer 126 may be provided on the red color filter RCF, the green color filter GCF, and the blue color filter BCF of the red, green, and blue subpixels RSP, GSP, and BSP and the second scattering pattern 131b of the white subpixel WSP.

The organic insulating layer 126 may include an organic material. The organic material may include one or more materials from among acrylic resins, phenolic resins, polyimide resins, unsaturated polyester resins, polyamide resins, benzocyclobutene, polyphenylene resins, and polyphenylene sulfide resins. The organic insulating layer 126 may be formed of a material having a refractive index of about 1.6 to 2.5, which is higher than that of the first and second scattering patterns 131a and 131b.

The organic insulating layer 126 corresponding to each emission portion REM, GEM, BEM, or WEM may have a flat upper surface by performing designated dry etching so that the organic insulating layer 126 in each emission portion REM, GEM, BEM, or WEM from the upper surface of each color filter RCF, GCF, or BCF or the second scattering pattern 131b remains with a similar or identical thickness. Even if the organic insulating layer 126 in each emission portion REM, GEM, BEM, or WEM has a flat upper surface, the upper surface of the organic insulating layer 126 in the green emission portion REM may be the highest and the upper surface of the organic insulating layer 126 in the white emission portion WEM may be the lowest due to a vertical thickness difference depending on whether the lower color filters RCF, GCF, and BCF and the first and second scattering patterns 131a and 131b are provided.

The contact hole may be provided in the organic insulating layer 126 on the first source/drain electrode 114 of the transistor TFT of each subpixel RSP, GSP, BSP, or WSP, so that the upper surface of the connection electrode 135 may be exposed.

The first electrode 151 of the light emitting device 150 may be connected to the connection electrode 135 of the transistor TFT in each subpixel RSP, GSP, BSP, or WSP through the contact hole of the organic insulating layer 126, thereby being conductively connected to the transistor TFT.

The light emitting device 150 includes a stack of the first electrode 151, the intermediate layer 152, and the second electrode 153.

The light emitting display device emits light downward, the first electrode 151 of the light emitting device 150 may include a transparent oxide electrode formed of indium tin oxide (ITO), indium zinc oxide (IZO), or indium tin zinc oxide (ITZO), and the second electrode 153 may include a reflective electrode.

The second electrode 153 may include a single layer structure formed of one material selected from aluminum (Al), silver (Ag), molybdenum (Mo), gold (Au), magnesium (Mg), calcium (Ca), and barium (Ba), or an alloy of two or more materials selected therefrom.

The edge of the first electrode 151 overlaps the bank 140.

The bank 140 may be disposed by reflecting a surface step on the upper surface of the organic insulating layer 126 between adjacent subpixels.

An encapsulation layer 160 that protects the light emitting device 150 is provided on the light emitting device 150.

The encapsulation layer 160 may be formed by alternately disposing, for example, one or more inorganic encapsulation layers and organic encapsulation layers.

The following experiments will examine light extraction effect by the scattering pattern of the present disclosure.

In the following experiments, a structure having a scattering pattern for a white subpixel will be defined as Experimental Example 1 EX1, and a structure not having a scattering pattern will be defined as Experimental Example 2 EX2.

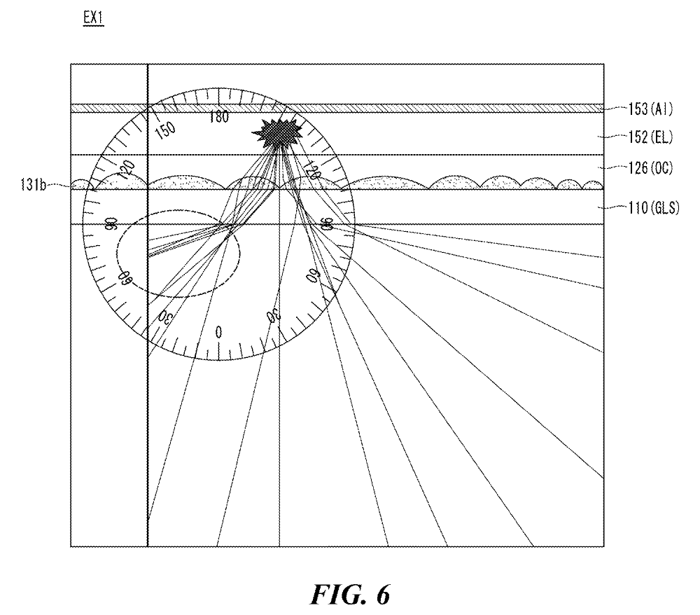

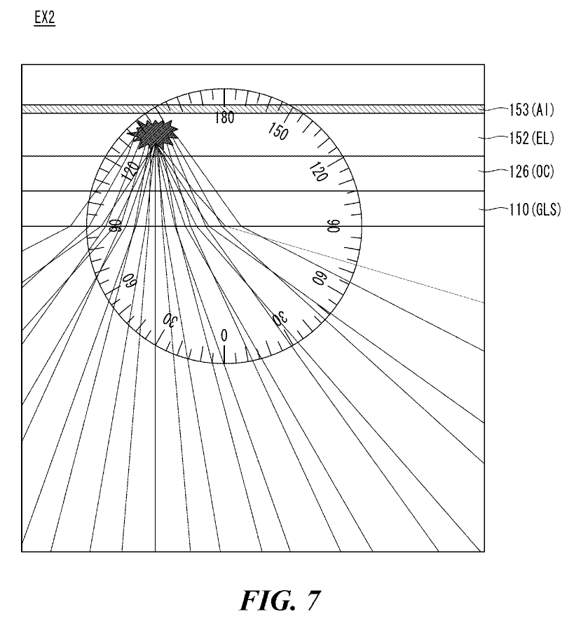

FIG. 6 is a diagram showing a light emission angle of Experimental Example 1. FIG. 7 is a diagram showing a light emission angle of Experimental Example 2.

Experimental Examples 1 and 2 EX1 and EX2 have a substrate (GLS) 110, an organic insulating layer (OC) 126, and a light emitting device (ED) 150 in common, and only Experimental Example 1 EX1 further has a second scatting pattern 131b between the substrate 110 and the organic insulating layer 126.

As shown in FIG. 6, in Experimental Example 1 EX1, it may be confirmed that light scattering is concentrated on the second scattering pattern 131b and light extraction is possible up to an angle of 70° to 80°, as in an area indicated by a dotted line where light substantially transmits the substrate 110.

On the other hand, as shown in FIG. 7, in Experimental Example 2 EX2, it may be confirmed that light generated from the light emitting device ED is hardly refracted or scattered by the organic insulating layer (OC) and the substrate 110, so that light extraction is possible within an angle of approximately 66°.

That is, the light emitting display device according to one embodiment of the present disclosure, like Experimental Example 1 EX1, has the scattering pattern 131b so that the light extraction angle is increased to be wider than direct light, thereby reducing luminance reduction when the viewing angle changes, maintaining luminance efficiency at a certain level or higher even when the viewing angle changes, and thus improving the luminance viewing angle.

In addition, the light emitting display device according to one embodiment of the present disclosure has the scattering patterns 131a and 131b together in at least the green subpixel GSP and the white subpixel WSP that have a dominant effect of changes in viewing angle of white light, thereby being capable of further improving the luminance viewing angle of white light.

Further, the light emitting display device according to one embodiment of the present disclosure has the scattering patterns 131a and 131b alternately disposed in adjacent subpixels in the row direction, and thus provides a vertical phase difference of the organic insulating layer 126 in the adjacent subpixels depending on presence or absence of the scattering patterns 131a and 131b, thereby increasing resistance to leakage current due to a long path in the bank 140 and the intermediate layer 152 disposed sequentially on the organic insulating layer 126 and thus significantly reducing or preventing the influence of the leakage current between the adjacent subpixels.

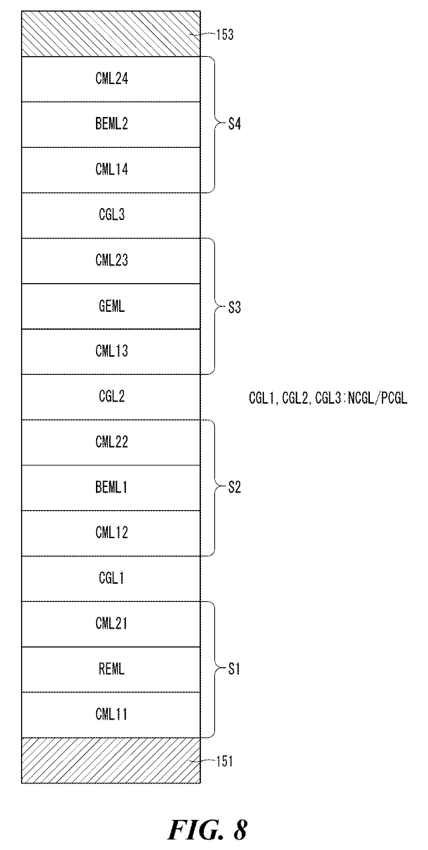

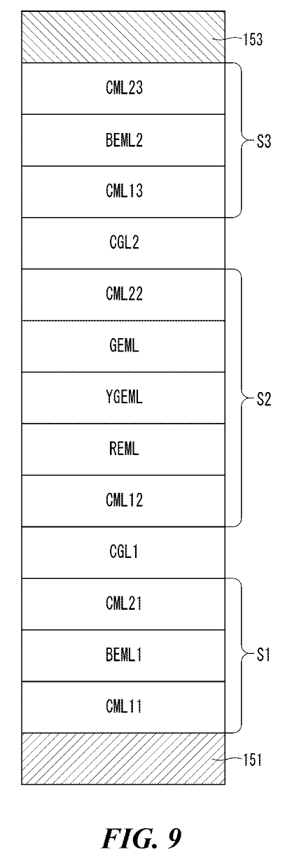

FIGS. 8 and 9 are cross-sectional views showing examples of light emitting devices of light emitting display devices according to embodiments of the present disclosure.

Further, as shown in FIGS. 8 and 9, the light emitting device of the light emitting display device of the present disclosure has a structure in which at least the intermediate layer 152 is provided in common in the respective subpixels RSP, GSP, BSP, and WSP.

For example, the light emitting device may include a plurality of emission stacks S1, S2, S3, and S4 between the first electrode 151 and the second electrode 153, and charge generation layers CGL1, CGL2, and CGL3 between the emission stacks S1, S2, S3, and S4, as shown in FIG. 8. In common, in the configuration of the light emitting device 150 of each subpixel RSP, GSP, BSP, and WSP, the light emitting device may emit white light, and the white light may be emitted as red light, blue light, and green light by passing through the red color filter RCF, the blue color filter BCF, and the green color filter GCF provided in the red subpixel RSP, the blue subpixel BSP, and the green subpixel GSP, respectively. In the green subpixel GSP, the first scattering pattern 131a is disposed under the green color filter GCF so that green light GL scattered in a wider direction may be emitted through the substrate 110, compared to the red and blue subpixels RSP and BSP that vertically emit red light RL and blue light BL as direct light through the substrate 110.

In addition, the white subpixel WSP emits white light from the light emitting device through the second scattering pattern 131b so that white light WL scattered in a wider direction than the white light from the light emitting device may be emitted.

For example, in the intermediate layer 152, a first emission stack S1 emitting red light, a second emission stack S2 emitting blue light, a third emission stack S3 emitting green light, and a fourth emission stack S4 emitting blue light may be sequentially stacked.

Each emission stack S1, S2, S3, or S4 may include an emission layer REML, BEML1, GEML, or BEML2, a first common layer CML11, CML12, CML13, or CML14 having hole transport properties and disposed under the emission layer REML, BEM1, GEML, or BEML2, and a second common layer CML21, CML22, CML23, or CML24 having electron transport properties and disposed on the emission layer REML, BEML1, GEML, or BEML2. The first common layers CML11, CML12, CML13, and CML14 may include a hole injection layer, a hole transport layer, an electron blocking layer, etc. The second common layers CML21, CML22, CML23, and CML24 may include a hole blocking layer, an electron transport layer, an electron injection layer, etc.

That is, FIG. 8 shows the intermediate layer 152 having a stacked arrangement of red, first blue, green, and second blue emission stacks S1, S2, S3, and S4 (R/B1/G/B2) in a direction from the first electrode 151 to the second electrode 153. As shown in FIG. 8, even if the light emitting device 150 is included in the same manner in each subpixel RSP, GSP, BSP, or WSP, the red color filter RCF, the blue color filter BCF, and the first scattering pattern 131a and the green color filter GSP are disposed between the light emitting devices 150 and the substrate 110, so that expression of an individual color different from white in each subpixel RSP, BSP, or GSP is possible, and the white subpixel WSP that does not have a color filter may express scattered white light by allowing white light emitted from the light emitting device 150 to pass through the second scattering pattern 131b.

FIG. 8 shows an example in which the intermediate layer 152 includes four emission stacks and three charge generation layers.

However, the light emitting devices according to the embodiments of the present disclosure are not limited thereto. For example, unlike the example shown in FIG. 8 in which when a plurality of emission stacks is disposed between the first and second electrodes, the emission stacks are disposed by color, a plurality of emission stacks may be disposed between the first and second electrodes in the order of a red emission stack, a green emission stack, and first and second blue emission stacks (R/G/B1/B2), in the order of a green emission stack, a red emission stack, and a first and second blue emission stack (G/R/B1/B2), or in the order of a first blue emission stack, a red emission stack, a green emission stack, and a second blue emission stack (B1/R/G/B2), or may be disposed in other orders.

Here, the reason why two blue emission stacks are disposed in the light emitting device is to compensate the relatively low efficiency of blue compared to other colors.

The above-described light emitting device including the first to fourth emission stacks S1, S2, S3, and S4 may emit white light when a voltage greater than or equal to a certain level is applied between the first electrode 151 and the second electrode 153.

Unlike the illustrated example, the intermediate layer of the light emitting device 150 may have a different arrangement of a plurality of emission stacks and charge generation layers.

FIG. 9 illustrates an example in which the light emitting device 150 has three emission stacks S1, S2, and S3 between the first electrode 151 and the second electrode 153. Each of the first and third stacks S1 and S3 may include a first or second blue emission layers BMEL1 or BEML2 that emits blue light, and the second stack S2 may include a plurality of phosphorescent emission layers REML, YGEML, and GEML that emit longer wavelengths than blue.

In addition, each emission stack S1, S2, or S3 may include an emission layer or an emission layer stack BEML1, REML/YGEML/GEML, or BEML2, a first common layer CML11, CML12, or CML13 having hole transporting properties under the emission layer or the emission layer stack BEML1, REML/YGEML/GEML, or BEML2, and a second common layer CML21, CML22, or CML23 having electron transport properties on the emission layer or the emission layer stack BEML1, REML/YGEML/GEML, or BEML2. The first common layers CML11, CML12, and CML13 may include a hole injection layer, a hole transport layer, an electron blocking layer, etc. The second common layers CML21, CML22, and CML23 may include a hole blocking layer, an electron transport layer, an electron injection layer, etc.

As described above, the light emitting display device according to the embodiments of the present disclosure has the scattering patterns 131a and 131b between the light emitting devices 150 and the substrate 110 in the emission path from the light emitting device 150 to the substrate 110, at least in the green emission portion and the white emission portion, in a structure having the light emitting device 150 including a plurality of stacks in common in subpixels, thereby being capable of improving a luminance viewing angle, and increasing resistance to the path of leakage current between adjacent subpixels due to a difference between the adjacent subpixels based on presence or absence of a color filter and presence or absence of a scattering pattern between the adjacent subpixels and thus preventing or significantly reducing the influence of the leakage current.

As is apparent from the above description, a light emitting display device according to the embodiments of the present disclosure may provide scattering patterns to subpixels that are dominant in luminance expression, thereby improving a luminance viewing angle.

The light emitting display device according to the embodiments of the present disclosure may provide a random wrinkle pattern on the upper surfaces of the scattering patterns so that the scattering patterns have no wavelength dependency, thereby improving the luminance viewing angle of white light.

The light emitting display device according to the embodiments of the present disclosure includes the scattering patterns provided on the emission sides of at least a white subpixel and a green subpixel, thereby being capable of reducing a luminance deviation depending on changes in the viewing.

The light emitting display device according to the embodiments of the present disclosure has different configurations overlapping an organic insulating layer between adjacent subpixels so that a bank is provided on the organic insulating layer having different vertical phases between the adjacent subpixels, thereby being capable of increasing the path of an intermediate layer between the adjacent subpixels and thus preventing or reducing leakage current between the adjacent subpixels. Accordingly, leakage emission between the adjacent subpixels due to the emission of a designated subpixel may be prevented and visibility may be improved.

The light emitting display device of the present disclosure provides the scattering patterns that are easy to pattern over a large area between a light emitting device and a substrate to predetermined subpixels, and varies a stack structure of the scatting pattern and a color filter between adjacent subpixels to increase the path of the intermediate layer between the adjacent subpixels, thereby being capable of preventing leakage current and thus preventing leakage between the adjacent subpixels. Therefore, in terms of improving the luminance viewing angle and preventing leakage emission, the light emitting display device of the present disclosure is sustainably applicable, thereby being capable of achieving Environmental, Social, and Governance (ESG) goals.

A light emitting display device according to one embodiment of the present disclosure may comprise a substrate comprising a red emission portion, a green emission portion, a blue emission portion, and a white emission portion spaced apart from each other, a red color filter at the red emission portion, a green color filter at the green emission portion, and a blue color filter at the blue emission portion, a first scattering pattern between the substrate and the green color filter, a second scattering pattern on the substrate at the white emission portion, an organic insulating layer configured to cover the red color filter, the green color filter, the blue color filter, and the second scattering pattern, a light emitting device on the organic insulating layer, the light emitting device comprising a plurality of first electrodes at the red emission portion, the green emission portion, the blue emission portion, and the white emission portion to be spaced apart from each other and a bank configured to expose the red emission portion, the green emission portion, the blue emission portion, and the white emission portion of the plurality of first electrodes.

In a light emitting display device according to one embodiment of the present disclosure, each of the first scattering pattern and the second scattering pattern may have a random wrinkle pattern on an upper surface thereof.

In a light emitting display device according to one embodiment of the present disclosure, each of the first scattering pattern and the second scattering pattern may have a plurality of curved planes protruding toward the organic insulating layer.

In a light emitting display device according to one embodiment of the present disclosure, an upper surface of the first scattering pattern may be in contact with the green color filter. An upper surface of the second scattering pattern may be in contact with the organic insulating layer. Un upper surface of the green color filter configured to overlap the first scattering pattern and an upper surface of the organic insulating layer configured to overlap the second scattering pattern may be flat.

In a light emitting display device according to one embodiment of the present disclosure, the first scattering pattern and the second scattering pattern may have the same vertical phase on the substrate. The first electrode at the green emission portion may have a higher vertical phase than the first electrodes at the red emission portion and the blue emission portion. The first electrode at the white emission portion may have a lower vertical phase than the first electrodes at the red emission portion and the blue emission portion.

In a light emitting display device according to one embodiment of the present disclosure, the first electrode at the green emission portion may be in contact with a flat upper surface of the organic insulating layer having a first vertical distance from the substrate. The first electrode at the white emission portion may be in contact with a flat upper surface of the organic insulating layer having a second vertical distance smaller than the first vertical distance from the substrate. The first electrodes at the red emission portion and the blue emission portion may be in contact with a flat upper surface of the organic insulating layer having a third vertical distance from the substrate between the first vertical distance and the second vertical distance.

In a light emitting display device according to one embodiment of the present disclosure, maximum thickness of the first scattering pattern may be less than a thickness of the green color filter.

In a light emitting display device according to one embodiment of the present disclosure, each of maximum thicknesses of the first scattering pattern and the second scattering pattern may be less than a maximum thickness of the organic insulating layer.

In a light emitting display device according to one embodiment of the present disclosure, the first scattering pattern may have a lower refractive index than the green color filter and the second scattering pattern may have a lower refractive index than the organic insulating layer.

In a light emitting display device according to one embodiment of the present disclosure, an upper surface of the organic insulating layer may have a first curved plane having a vertical phase changed at an area surrounding the green emission portion and a second curved plane having a vertical phase changed at an area surrounding the white emission portion.

The bank may be disposed on the first curved plane and the second curved plane.

In a light emitting display device according to one embodiment of the present disclosure, the first curved plane may be provided between the green emission portion and the red emission portion, and between the green emission portion and the blue emission portion. The second curved plane may be provided between the white emission portion and the blue emission portion and between the white emission portion and the red emission portion.

In a light emitting display device according to one embodiment of the present disclosure, the light emitting device may comprise an intermediate layer on the plurality of first electrodes and a second electrode on the intermediate layer. The intermediate layer may be disposed on an upper surface of the plurality of first electrodes at each of the red emission portion, the green emission portion, the blue emission portion, and the white emission portion, and on an upper surface of the bank.

In a light emitting display device according to one embodiment of the present disclosure, the light emitting device may have the same structure at the red emission portion, the green emission portion, the blue emission portion, and the white emission portion.

The light emitting device may comprise an intermediate layer comprising a plurality of emission stacks and at least one charge generation layer on the plurality of first electrodes, and a second electrode on the intermediate layer.

Each of the plurality of emission stacks may comprise a hole transport layer, at least one emission layer, and an electron transport layer.

In a light emitting display device according to one embodiment of the present disclosure, the light emitting device comprises an intermediate layer on the plurality of first electrodes, and a second electrode on the intermediate layer.

The intermediate layer may comprise a red emission stack, a first charge generation layer, a first blue emission stack, a second charge generation layer, a green emission stack, a third charge generation layer, and a second blue emission stack between the first electrode and the second electrode.

A light emitting display device according to one embodiment of the present disclosure may further comprise a pixel circuit between the substrate and the organic insulating layer. The pixel circuit may overlap the bank.

Through the above description, it should be apparent to those skilled in the art that various changes and modifications are possible without departing from the technical spirit of the present disclosure. Therefore, the technical scope of the present disclosure should not be limited to the above detailed description and the disclosure does not limit the scope of the claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate comprising a red emission portion, a green emission portion, a blue emission portion, and a white emission portion spaced apart from each other;
a red color filter at the red emission portion, a green color filter at the green emission portion, and a blue color filter at the blue emission portion;
a first scattering pattern between the substrate and the green color filter;
a second scattering pattern on the substrate at the white emission portion;
an organic insulating layer configured to cover the red color filter, the green color filter, the blue color filter, and the second scattering pattern;
a light emitting device on the organic insulating layer, the light emitting device comprising a plurality of first electrodes at the red emission portion, the green emission portion, the blue emission portion, and the white emission portion, the plurality of first electrodes at the red, green, blue, and white emission portions spaced apart from each other; and
a bank configured to expose the plurality of first electrodes at the red emission portion, the green emission portion, the blue emission portion, and the white emission portion.

2. The light emitting display device according to claim 1, wherein each of the first scattering pattern and the second scattering pattern has a random wrinkle pattern on an upper surface thereof.

3. The light emitting display device according to claim 1, wherein each of the first scattering pattern and the second scattering pattern has a plurality of curved planes protruding toward the organic insulating layer.

4. The light emitting display device according to claim 1, wherein:
an upper surface of the first scattering pattern is in contact with the green color filter, and an upper surface of the second scattering pattern is in contact with the organic insulating layer; and
an upper surface of the green color filter overlaps the first scattering pattern and an upper surface of the organic insulating layer overlaps the second scattering pattern are flat.

5. The light emitting display device according to claim 1, wherein:
the first scattering pattern and the second scattering pattern have the same vertical phase on the substrate;
a first one of the plurality of first electrodes at the green emission portion has a higher vertical phase than second ones of the plurality of first electrodes at the red emission portion and the blue emission portion; and
a third one of the plurality of first electrodes at the white emission portion has a lower vertical phase than the second ones of the plurality of first electrodes at the red emission portion and the blue emission portion.

6. The light emitting display device according to claim 5, wherein:
the first one of the plurality of first electrodes at the green emission portion is in contact with a flat upper surface of the organic insulating layer at a first location of the flat upper surface having a first vertical distance from the substrate;
the third one of the plurality of first electrodes at the white emission portion is in contact with the flat upper surface of the organic insulating layer at a second location of the flat upper surface having a second vertical distance less than the first vertical distance from the substrate; and
the second ones of the plurality of first electrodes at the red emission portion and the blue emission portion are in contact with the flat upper surface of the organic insulating layer at a third location of the flat upper surface having a third vertical distance from the substrate between the first vertical distance and the second vertical distance.

7. The light emitting display device according to claim 1, wherein a maximum thickness of the first scattering pattern is less than a thickness of the green color filter.

8. The light emitting display device according to claim 1, wherein a maximum thickness of the first scattering pattern and a maximum thickness of the second scattering pattern are each less than a maximum thickness of the organic insulating layer.

9. The light emitting display device according to claim 1, wherein:
the first scattering pattern has a lower refractive index than the green color filter; and
the second scattering pattern has a lower refractive index than the organic insulating layer.

10. The light emitting display device according to claim 1, wherein:
an upper surface of the organic insulating layer has a first curved plane at an area surrounding the green emission portion, and a second curved plane at an area surrounding the white emission portion; and
the bank is disposed on the first curved plane and the second curved plane.

11. The light emitting display device according to claim 10, wherein:
the first curved plane is provided between the green emission portion and the red emission portion, and between the green emission portion and the blue emission portion; and
the second curved plane is provided between the white emission portion and the blue emission portion, and between the white emission portion and the red emission portion.

12. The light emitting display device according to claim 10, wherein:
the light emitting device comprises an intermediate layer on the plurality of first electrodes and a second electrode on the intermediate layer; and
the intermediate layer is disposed on an upper surface of the plurality of first electrodes at each of the red emission portion, the green emission portion, the blue emission portion, and the white emission portion, and on an upper surface of the bank.

13. The light emitting display device according to claim 1, wherein:
the light emitting device has the same structure at the red emission portion, the green emission portion, the blue emission portion, and the white emission portion;
the light emitting device comprises an intermediate layer comprising a plurality of emission stacks and at least one charge generation layer on the plurality of first electrodes, and a second electrode on the intermediate layer; and
each of the plurality of emission stacks comprises a hole transport layer, at least one emission layer, and an electron transport layer.

14. The light emitting display device according to claim 1, wherein the light emitting device comprises an intermediate layer on the plurality of first electrodes, and a second electrode on the intermediate layer,
wherein the intermediate layer comprises a red emission stack, a first charge generation layer, a first blue emission stack, a second charge generation layer, a green emission stack, a third charge generation layer, and a second blue emission stack between the first electrode and the second electrode.

15. The light emitting display device according to claim 1, further comprising a pixel circuit between the substrate and the organic insulating layer,
wherein the pixel circuit overlaps the bank.
